(19) United States
(12) Patent Application Publication
(10) Pub. No.: US 2012/0076165 A1
(43) Pub. Date: Mar. 29, 2012

(54) ASYMMETRICALLY CLADDED LASER DIODE

(75) Inventors: Arpan Chakraborty, Goleta, CA (US); You-Da Lin, Goleta, CA (US); Shuji Nakamura, Santa Barbara, CA (US); Steven P. Denbaars, Goleta, CA (US)

(73) Assignee: THE REGENTS OF THE UNIVERSITY OF CALIFORNIA, Oakland, CA (US)

(21) Appl. No.: 13/376,315

(22) PCT Filed: Jun. 7, 2010
(86) PCT No.: PCT/US10/37629

§ 371 Date: Dec. 5, 2011

Related U.S. Application Data
(60) Provisional application No. 61/184,668, filed on Jun. 5, 2009.

(51) Int. Cl. H01S 5/323; H01L 21/30

(52) U.S. Cl. 372/45.01; 438/31; 257/E21.211

(57) ABSTRACT

A light emitting active region between a first cladding layer and a second cladding layer, wherein the first cladding layer has a lower refractive index than a refractive index of the second cladding layer, and the first cladding layer and the second cladding layer are III-nitride based.

### CROSS-REFERENCE TO RELATED APPLICATIONS

This application claims the benefit under 35 U.S.C. Section 119(e) of co-pending and commonly assigned U.S. Provisional Patent Application Ser. No. 61/184,668, filed on Jun. 5, 2009, by Arpan Chakraborty, You-Da Lin, Shuji Nakamura, and Steven P. DenBaars, entitled “ASYMMETRICALLY CLADDED LASER DIODE” attorney's docket number 30794.314-US-P1 (2009-614-1);

which application is incorporated by reference herein.

This application is related to co-pending and commonly-assigned U.S. Utility application Ser. No. ______, filed on same date herewith, by Arpan Chakraborty, You-Da Lin, Shuji Nakamura, and Steven P. DenBaars, entitled “LONG WAVELENGTH NONPOLAR AND SEMIPOLAR (Al, Ga, In)N BASED LASER DIODES,” attorneys' docket number 30794.315-US-U1 (2009-616-2), which application claims the benefit under 35 U.S.C. Section 119(e) of co-pending and commonly assigned U.S. Provisional Application Ser. No. 61/184,729, filed on Jun. 5, 2009, by Arpan Chakraborty, You-Da Lin, Shuji Nakamura, and Steven P. DenBaars, entitled “LONG WAVELENGTH m-PLANE (Al, Ga, In)N BASED LASER DIODES,” attorneys' docket number 30794.315-US-P1 (2009-616-1);

which applications are incorporated by reference herein.

### STATEMENT REGARDING FEDERALLY SPONSORED RESEARCH AND DEVELOPMENT

This invention was made with Government support under Grant No. FA8718-08-C-0005 awarded by DARPA-VIGIL. The Government has certain rights in this invention.

### BACKGROUND OF THE INVENTION

1. Field of the Invention

This invention relates to laser diodes (LDs).

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

There are two basic GaN based laser diode (LD) designs and both have symmetric cladding layers:
1. AlGaN cladded structures, with InGaN or GaN waveguiding layers [1,2].
2. AlGaN clad-free, or GaN cladded structures, with InGaN guiding layers [3,4]

In the AlGaN cladded structures, the top and bottom cladding are both AlGaN layers. In the AlGaN clad-free structures, none of the cladding layers contain aluminum (Al) alloy; instead, GaN is used for the cladding layers.

For nonpolar LDs, a novel structure without AlGaN cladding was proposed by Feezell et al. [3]. In typical violet LD structures, ˜7% Al-composition AlGaN layers are commonly used as cladding layers. For blue-green LDs, some groups have been using thick AlGaN cladding layers to achieve a higher optical confinement factor (Γ) [2,5].

However, as shown in [6], use of upper and lower AlGaN cladding layers with high Al composition usually causes macroscopic cracking From the material point of view, p-AlGaN as an upper cladding material has further drawbacks. The optimized growth temperature for p-AlGaN is usually higher than that for p-GaN, which causes heat damage to InGaN multiple quantum wells (MQW) [7]. On the other hand, low temperature growth of p-AlGaN results in poor crystal quality and low electrical conductivity. In addition, the higher activation energy of acceptors in AlGaN results in low hole density, which manifests as high series resistance and reduced hole injection into the active region [8].

Therefore, eliminating the AlGaN cladding layer (in particular, p-type AlGaN) from the device structure, while maintaining the confinement factor Γ, has advantages. Previous AlGaN cladding-free LDs were based on 5 periods of 8 nm thick quantum wells (QWs) [3], where F could be kept high. In this type of AlGaN cladding-free structure, the thick quantum well (QW) was the key to obtain a high F. However, this thick QW was viable for low indium composition (In <10%) InGaN, but it was difficult to fabricate LDs emitting in the wavelength region beyond blue (In>16%), according to the present invention's preliminary experiments.

Consequently, there is a need in the art for structures with improved cladding layers. The present invention satisfies this need.

### SUMMARY OF THE INVENTION

To overcome the limitations in the prior art described above, and to overcome other limitations that will become apparent upon reading and understanding the present specification, the present invention describes an asymmetric cladded semiconductor LD structure, in particular (Al, Ga, In)N based blue or green LD structures. The invention features a lower refractive index material, like AlGaN, for the bottom cladding layer, and a higher refractive index material, like GaN, for the upper cladding layer. This structure has several advantages over conventional LD structures that have symmetric cladding on either side of the active region. This structure is highly advantageous for nonpolar and semipolar GaN based LDs where it is possible to grow thicker quantum wells.

For example, the present invention discloses a III-nitride based LD structure, comprising a light emitting active region between a first cladding layer and a second cladding layer, wherein (1) the first cladding layer has a lower refractive index than a refractive index of the second cladding layer, thereby providing an asymmetric structure, and (2) the active region, the first cladding layer, and the second cladding layer are comprised of III-nitride based material compositions.

The active region is typically between a first waveguiding layer and a second waveguiding layer; the first waveguiding layer is typically between the active region and the first cladding layer, and the second waveguiding layer is typically between the active region and the second cladding layer. The first cladding layer may be AlGaN, the second cladding layer may be GaN, the first waveguiding layer may be InGaN, and the second waveguiding layer may be InGaN, for example.

The first waveguiding layer and the second waveguiding layer may be comprised of different III-nitride material compositions. For example, the first cladding layer and the second cladding layer may be comprised of material compositions other than AlGaN; the first cladding layer and the second cladding layer may be comprised of different AlGaN material compositions; an aluminum (Al) composition of the first cladding layer may be higher than an Al composition of the second cladding layer; the first cladding layer and the second cladding layer may be comprised of different InGaN material compositions; the first cladding layer and the second cladding layer are comprised of different AlInGaN material compositions.

The first waveguiding layer and the second guiding layer may comprise InGaN with an In composition greater than 5%. The first waveguiding layer and the second waveguiding layer may comprise InₓGa₁₋ₓN with x between 5 and 10%, the first cladding layer comprises n-Al_{0.05}Ga_{0.95}N, and the second cladding layer comprises p-GaN.

An aluminum containing electron blocking layer (EBL) may be between the active region and the second cladding layer, wherein the first cladding layer, the second cladding layer, and the aluminum containing EBL may place a peak of an optical mode of the light closer to a center of the active region as compared to a position of a peak of an optical mode in a symmetric cladded structure.

The second cladding layer may be an upper cladding layer, the first cladding layer may be a bottom cladding layer, and a thickness and material composition of the bottom cladding layer may create asymmetric in-plane strain, thereby increasing an ease of cleaving of the laser diode structure as compared to cleaving an AlGaN clad free laser diode structure.

A material composition and thickness of the bottom cladding layer may increase the modal confinement, resulting in lower threshold current density and improved lasing behavior, as compared to a symmetric laser diode structure.

The LD may further comprise a first facet and a second facet defining an optical cavity of the laser diode structure, wherein the first facet and the second facet are seamlessly cleaved facets as compared to cleaved facets of an AlGaN clad free laser diode structure.

The active region may be nonpolar or semipolar, and on a nonpolar or semipolar substrate.

Thus, the LD may further comprise: the first cladding layer, comprising a first material, deposited on an n-GaN layer; the first waveguiding layer deposited on the first cladding layer; the active layer deposited on the first waveguiding layer; the EBL deposited on the active layer; the second waveguiding layer deposited on the EBL layer; the second cladding layer, comprising a second material, deposited on the second waveguiding layer, the second material having a higher refractive index than the refractive index of the first material; and a contact layer deposited on the second cladding layer.

The active layer may include an InGaN quantum well with an In composition sufficient to emit light having wavelengths corresponding to blue light, wavelengths longer than blue light, or with an In composition greater than 16%.

The present invention further discloses a method of fabricating a III-nitride laser diode structure, comprising: providing an asymmetric structure by positioning a light emitting active region between a first cladding layer and a second cladding layer, wherein: (1) the first cladding layer has a lower refractive index than a refractive index of the second cladding layer, thereby providing an asymmetric structure, and (2) the active region, the first cladding layer and the second cladding layer are comprised of III-nitride based material compositions.

### BRIEF DESCRIPTION OF THE DRAWINGS

Referring now to the drawings in which like reference numbers represent corresponding parts throughout:

FIG. 1 shows schematic cross-sections of (a) a symmetric LD structure with AlGaN cladding, (b) a symmetric LD structure with GaN cladding, and (c) an asymmetric LD structure.

FIG. 2 is a comparison of refractive index and optical mode (arbitrary units, a.u.) profiles, for a symmetric p-Al_{0.05}GaN/n-Al_{0.05}GaN cladding structure (dashed curve, confinement factor Γ=2.77), a GaN-cladding structure (dotted curve, Γ=2.37), and an asymmetric p-GaN/n-Al_{0.05}GaN structure (solid curve, Γ=2.53), plotting refractive index and optical mode profile as a function of distance along the growth direction z (micrometers, μm) of each of the LD structures.

FIG. 3 shows (a) the dependency of the optical mode confinement factor and (b) the internal loss of p-Al_{0.05}GaN/n-Al_{0.05}GaN cladding (dashed curve), GaN-cladding (dotted curve), and p-GaN/n-Al_{0.05}GaN cladding (solid curve) structures, on the indium composition of the InGaN guiding layer, wherein the inset in (b) shows the optical mode (dashed curve) and refractive index (n) (solid curve) profile, as a function of distance z (μm) along the growth direction, for the p-Al_{0.05}GaN/n-Al_{0.05}GaN cladding structure without an InGaN guiding layer.

FIG. 4 shows (a) confinement factor and (b) internal loss (cm⁻¹) of p-GaN/n-Al_{0.05}GaN cladding structures with GaN (dotted curve), In_{0.05}Ga_{0.95}N (dashed curve), and In_{0.1}Ga_{0.9}N (solid curve) guiding layers, as a function of the Al composition in the AlGaN cladding layer.

FIG. 5 shows light output power (milliwatts, mW) vs. current (I), in milliamps (mA), of an asymmetric p-GaN/n-AlGaN cladding LD with lasing wavelength (a) 443 nm and (b) 465 nm, wherein the curves A, B and C in (a) and (b) are for different devices from one sample, showing the performance distribution, the inset in (a) shows spontaneous emission spectra at a drive current of I=10 mA (emitting at a peak wavelength λ=464 nm), I=0.7×Ith (Ith is threshold current), and lasing at I>Ith (lasing emitting at a peak wavelength λ=443 nm), and the inset in (b) shows spontaneous emission spectra at a drive current of I=10 mA (emitting at a peak wavelength λ=483 nm), I=0.6×Ith, and lasing for I>Ith (lasing and emitting at a peak wavelength λ=465 nm).

FIG. 6 shows (a) an image showing cleaved facets of an asymmetric cladded laser, and (b) cleaved facets of a symmetric AlGaN clad-free laser, wherein the scale is 200 μm in both (a) and (b).

FIG. 7 is a flowchart illustrating a method of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Nomenclature

GaN and its ternary and quaternary compounds incorporating aluminum and indium (AlGaN, InGaN, AlInGaN) are commonly referred to using the terms (Al, Ga, In)N, III-nitride, Group III-nitride, nitride, Al_{(1-x-y)}In_{y}GaₓN where 0≦x≦1 and 0≦y≦1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al, Ga, In)N materials within the scope of the invention may further include minor quantities of dopants and/or other impurity or inclusional materials.

Moreover, throughout this disclosure, the prefixes n-, p-, and p⁺⁺- before the layer material denote that the layer material is n-type, p-type, or heavily p-type doped, respectively. For example, n-GaN indicates the GaN is n-type doped.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semipolar planes of the crystal. The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index.

Technical Description

This invention employs an n-type AlGaN cladding layer, where typical Al composition can range from 2-10%, sandwiched between an n-type GaN substrate and a n-InGaN or n-GaN guiding layer. A relatively high In (5-10%) containing InGaN guiding layer is preferred for longer wavelength LDs.

The guiding layer is followed by the active region comprising InGaN wells and GaN or InGaN or AlInGaN barriers. For typical LD structures, the number of periods can range from 2 to 6, the well width can range from 1 to 8 nm, and the barrier width from 6 to 15 nm. Typical thickness for the last barrier is 5 to 20 nm. The last barrier is followed by an AlGaN EBL, for which the typical thickness and Al concentration range from 6-20 nm and 10-30%, respectively. The AlGaN EBL is typically doped with Mg.

A p-type InGaN or GaN layer is used as the upper guiding layer, capped with a thick p-type GaN layer as the upper cladding.

The best way of practicing this invention would be to use it along with a nonpolar or semipolar AlGaN clad-free structure, especially for blue-green spectral region emission.

Device Structures

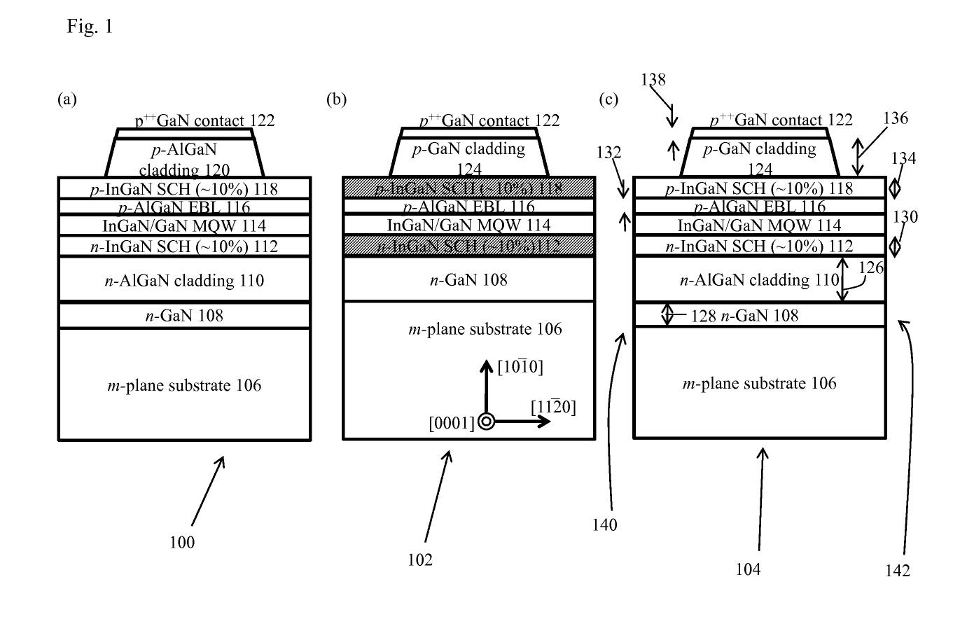

FIGS. 1(a) and 1(b) are schematic cross-sections of symmetric LD structures 100, 102 with AlGaN and GaN cladding, respectively. FIG. 1(c) is a schematic cross-section of an asymmetric LD structure 104.

In FIG. 1(a), the LD structure 100 comprises an m-plane substrate 106, an n-GaN layer 108 on the m-plane substrate 106, an n-AlGaN cladding layer 110 on the n-GaN layer 108, an n-InGaN separate confinement heterostructure (SCH) layer 112 (with ˜10% In composition) on the n-AlGaN cladding layer 110, an InGaN/GaN multiple quantum well (MQW) active layer 114 on the n-InGaN SCH layer 112, a p-AlGaN EBL 116 on the active layer 114, a p-InGaN SCH 118 (with ˜10% In composition) on the p-AlGaN EBL 116, a p-AlGaN cladding layer 120 on the p-InGaN SCH 118, and a p⁺⁺-GaN contact layer 122 on the p-AlGaN cladding layer 120.

In FIG. 1(b), the LD structure 102 comprises an m-plane substrate 106, an n-GaN layer 108 on the m-plane substrate 106, an n-InGaN SCH layer 112 (with ˜10% In composition) on the n-GaN layer 108, an InGaN/GaN MQW active layer 114 on the n-InGaN SCH layer 112, a p-AlGaN EBL 116 on the active layer 114, a p-InGaN SCH 118 (with ˜10% In composition) on the p-AlGaN EBL 116, a p-GaN cladding layer 124 on the p-InGaN SCH 118, and a p⁺⁺-GaN contact layer 122 on the p-GaN cladding layer 124. The arrows in FIG. 1(b) indicate the [10-10] direction and [11-20] direction, and the circle within a circle in FIG. 1(b) illustrates the [0001] direction (perpendicular to, and out of the plane of FIG. 1(b)).

In FIGS. 1(a) and 1(b), the active layer 114 is a 3 period MQW composition of 3 nm In_{0.26}Ga_{0.74}N well and 10 nm In_{0.03}Ga_{0.97}N barrier with a 10 nm thick EBL 116 of Al_{0.2}Ga_{0.8}N. 50 nm thick InₓGa₁₋ₓN (x˜6-10%) layers were used as upper 118 and lower 112 waveguides. In FIG. 1(a), the cladding layers 110 and 120 are 1 μm and 0.5 μm thick n-Al_{0.05}Ga_{0.95}N and p-Al_{0.05}Ga_{0.95}N cladding layers, respectively. In FIG. 1(b), the cladding layers 108, 124 are respectively 1 μm and 0.5 μm thick n-GaN and p-GaN cladding layers.

FIG. 1(c) illustrates an embodiment of the present invention, comprising an n-type lower AlGaN/GaN cladding layer 110 (e.g., alternating layers of a 5 nm thick AlGaN:Si (i.e., Si doped AlGaN) layer and a 5 nm thick GaN:Si (Si doped GaN) layer, for a total cladding layer 110 thickness 126 of 1 μm and average Al concentration of 6.4%), sandwiched between n-type GaN 108 (n-GaN) (e.g., with a 4 thickness 128) and an n-type InGaN (n-InGaN) lower guiding layer 112 (e.g., an n-InGaN SCH with approximately 5-10% In composition a and 50 nm thickness 130).

The active region 114 on the lower guiding layer 112 comprises an InGaN MQW (e.g., 3 period MQW with 5 nm thick InGaN wells and 10 nm thick InGaN barriers having 26% and 3% In composition, respectively).

An AlGaN EBL 116 (e.g., having a 10 nm thickness 132) is on the MQW 114, a p-type InGaN layer 118 (e.g., a p-InGaN SCH with approximately 5-10% In composition and a 50 nm thickness 134), on the EBL 116, is the upper guiding layer 118, and a p-type GaN (p-GaN) layer 124 (e.g., having a 500 nm thickness 136), on the upper guiding layer 118, is an upper cladding 124.

FIG. 1(c) also shows the structure comprises a nonpolar m-plane GaN substrate 106 and is capped with a p⁺⁺-type GaN cap 122 (e.g., having a 100 nm thickness 138).

The structure may also have an n-GaN spacer layer (e.g., 50 nm thick) between the lower AlGaN/GaN cladding layer 110 and the n-InGaN lower guiding layer 112, and an unintentionally doped (UID) GaN layer (e.g., 10 nm thick) between the active region 114 and the EBL 116.

Waveguide layers 112, 118 are used as waveguides (e.g., as a light pipe, for example). Cladding layers 110, 124, generated by index contrast to the waveguide 112, 118 (and acting, e.g., as a mirror, for example) help to confine the mode within the waveguide 112, 118, and prevent mode leakage into either the substrate 106 at the bottom or the metal at the top (e.g., a metal contact on layer 122).

Mg doping concentrations for EBL, p-guiding layers, p-cladding layers, and p-contact layers in FIG. 1(a)-(c) were respectively 2, 1, 3, 5×10¹⁹ cm⁻³. However, other doping concentrations and materials could be used. For example, the Mg doping density in the p-guiding layer might be reduced to suppress absorption coefficient α (cm⁻¹).

Device Simulations

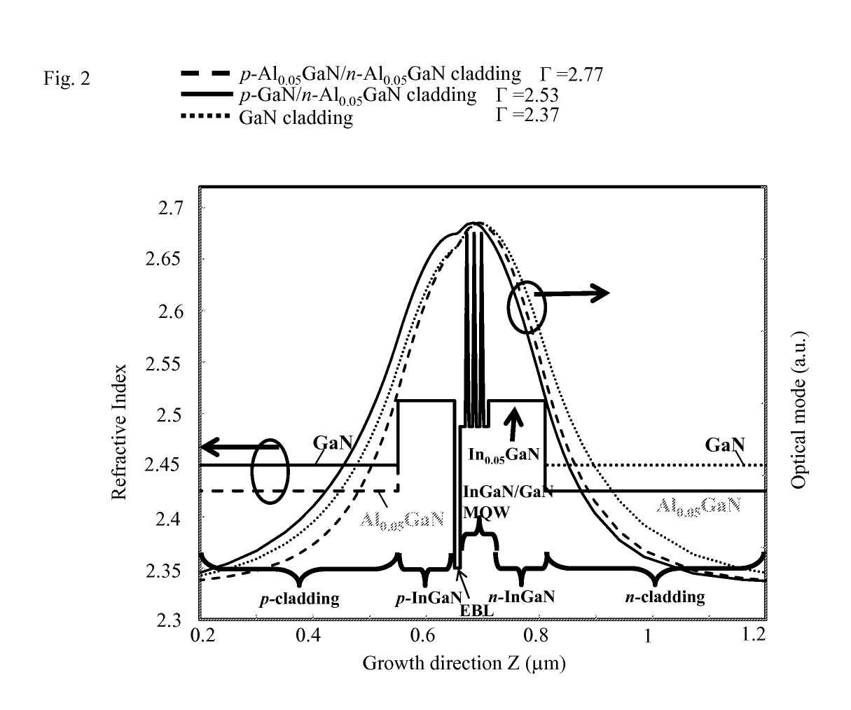

FIG. 2 is a comparison of refractive index and optical mode profiles, for symmetric and asymmetric structures, as a function of distance along the growth direction z, illustrating an LD structure wherein a peak of an optical mode of the light emitted by the active region (comprising quantum wells) is at a center (or closer to a center) of the active region (e.g., closer to the light emitting QWs), as compared to a position of a peak of an optical mode in a symmetric cladded LD structure. FIG. 2 shows the profiles are for LD structures which comprise an active region (an InGaN/GaN MQW) between an n-InGaN waveguiding layer and a p-InGaN waveguiding layer; the n-InGaN waveguiding layer between the active region and an n-cladding layer, the p-InGaN waveguiding layer between the active region, and the a p-cladding layer, and an aluminum containing EBL between the active region and p-cladding layer. In the symmetric structures, the p-cladding and n-cladding are p-Al_{0.05}GaN and n-Al_{0.05}GaN or p-GaN and n-GaN, respectively. In the asymmetric structure the p-cladding is p-GaN and the n-cladding is n-Al_{0.05}GaN. Without being bound to a specific scientific theory, it may be considered that the first cladding layer (n-cladding layer), second cladding layer (p-cladding layer), and the aluminum containing EBL place a peak of an optical mode of the light at a center of the active region as compared to a position of a peak of an optical mode in a symmetric cladded structure.

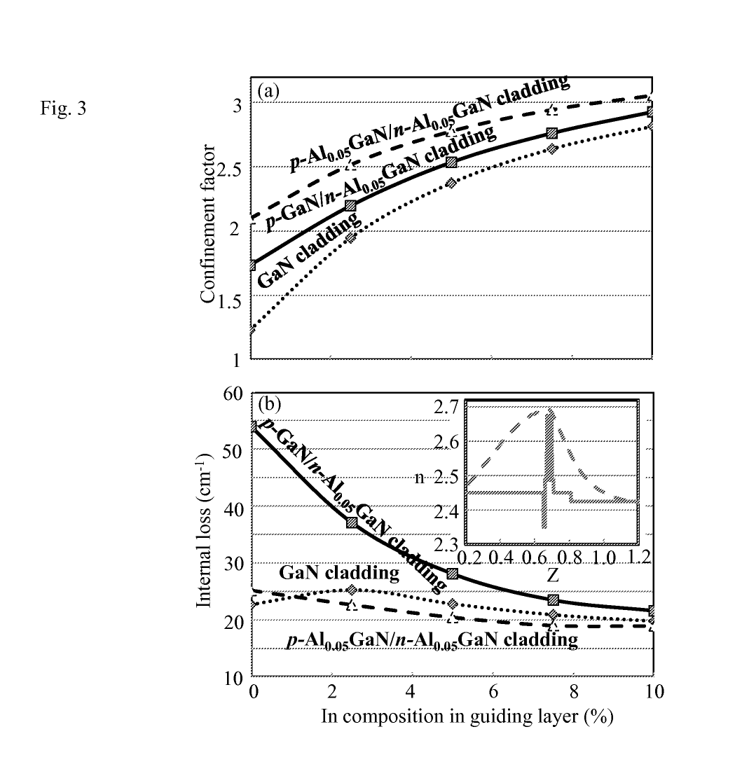

FIG. 3 shows (a) the dependency of the optical mode confinement factor Γ and (b) the internal loss of p-Al_{0.05}GaN/n-Al_{0.05}GaN cladding, GaN-cladding and p-GaN/n-Al_{0.05}GaN cladding structures on the indium composition of the InGaN guiding layer. The In composition is preferably, although not limited to, more than 5%.

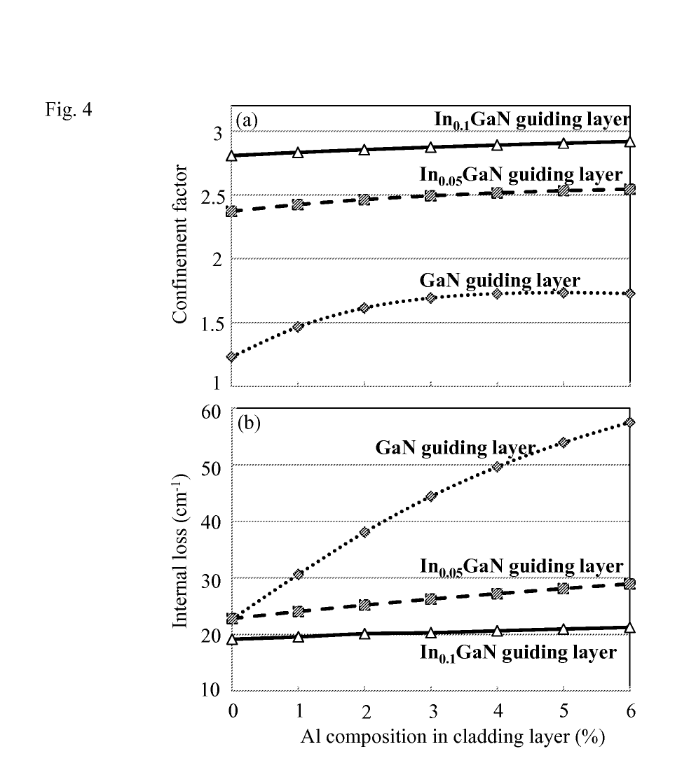

FIG. 4 shows (a) confinement factor and (b) internal loss of p-GaN/n-Al_{0.05}GaN cladding structure with GaN, In_{0.05}Ga_{0.95}N, and In_{0.1}Ga_{0.9}N guiding layers, as a function of the Al composition in the AlGaN cladding layer. The preferred composition of Al is a minimum of 3% (at least 3%, although not limited to this composition).

Experimental Results

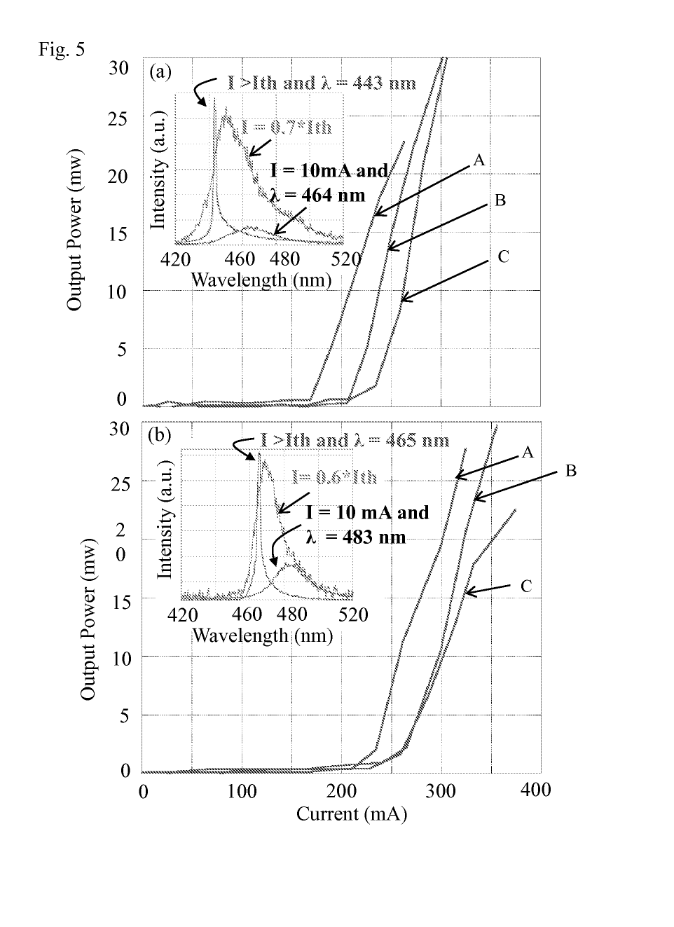

FIG. 5 shows light output power vs. current curves of an asymmetric p-GaN/n-AlGaN cladding LD, for lasing wavelength (a) 443 nm and (b) 465 nm, wherein the inset in (a) shows spontaneous emission at 10 mA and 0.7×Ith (Ith is threshold current), and lasing spectra and the inset in (b) shows spontaneous emission at 10 mA and 0.6×Ith, and lasing spectra. These LDs have Ith of at most 200 mA and a current density of at most 19 kA/cm² (for uncoated laser facets), or at least comparable to the devices reported in [2].

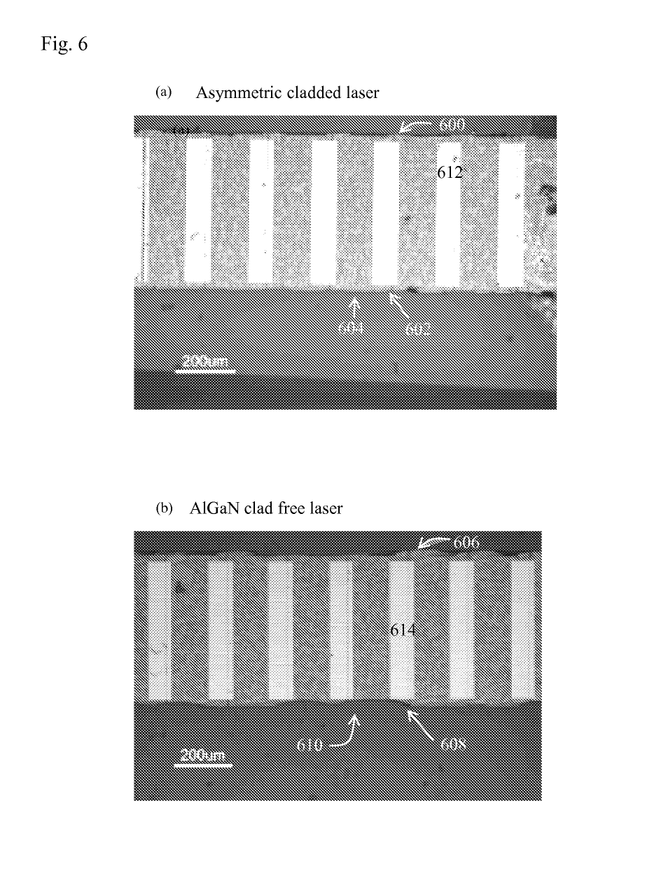

FIG. 6(a) is an image showing cleaved facets 600, 602 of an asymmetric cladded laser 604, wherein the scale is 200 μm. FIG. 6(b) is an image showing cleaved facets 606, 608 of a symmetric AlGaN clad-free laser 610, wherein the scale is 200 μm. Also shown are metal contacts 612, 614 on the p⁺⁺ GaN contact layer 122 of the LDs 604, 610.

Thus, FIG. 1(c) and FIG. 6(a)-(b) illustrate an LD structure comprising a first facet 140, 600 and a second facet 142, 602 defining an optical cavity of the LD 604, wherein the first facet 124, 600 and the second facet 126, 602 are seamlessly cleaved facets as compared to cleaved facets of an AlGaN clad free LD (i.e., the “as cleaved” surfaces of facets 140, 600, 142, 602 are more optically smooth than the surface of “as cleaved” facets of an AlGaN clad free LD. Without being bound by a particular theory, the first cladding layer 110 may be a bottom cladding layer, the second cladding layer 124 may be an upper cladding layer, wherein a thickness 126 and material composition of the bottom cladding layer creates asymmetric in-plane strain, thereby increasing an ease of cleaving of the LD structure 104, as compared to cleaving an AlGaN clad free LD structure.

The straight facets mean the angle between facets and laser ridge is typically, although not limited to, less than 5 degrees.

The range of cladding layer thickness is typically from 500 nm to 2 μm (although not limited to this range). The range of thickness for the guiding layers is typically from 25 nm to 150 nm (although not limited to this range).

Process Steps

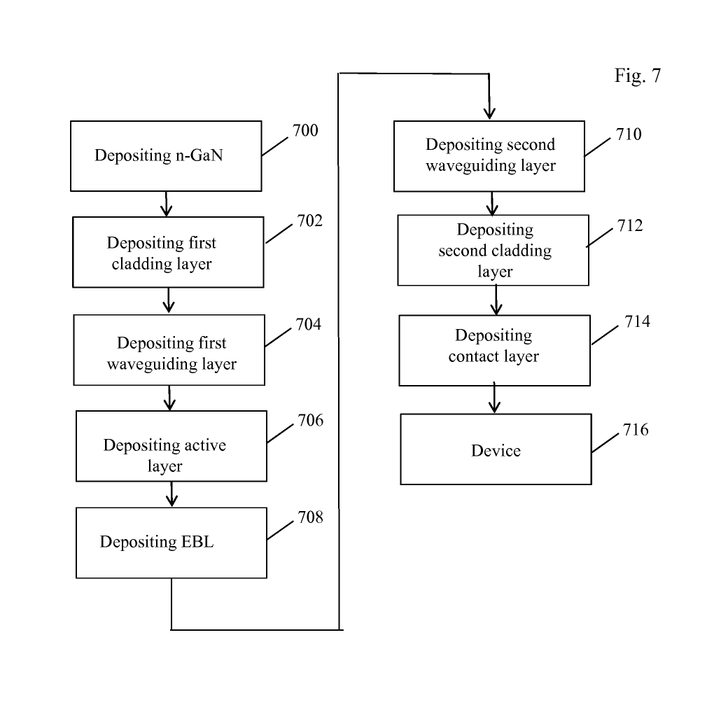

FIG. 7 is a flow chart illustrate a method of fabricating the III-nitride LD structure 104 of FIG. 1(c), comprising providing an asymmetric structure by positioning a light emitting active region 114 between a first cladding layer 110 and a second cladding layer 124, wherein (1) the first cladding layer 110 has a lower refractive index than a refractive index of the second cladding layer 124, thereby providing the asymmetric structure, and (2) the active region 114, the first cladding layer 110 and the second cladding layer 124 are comprised of III-nitride based material compositions. The positioning may comprise the following steps.

Block 700 represents depositing an n-GaN layer 108 on a substrate 106, for example on a non-polar or semi-polar substrate (so that the active layer 114 is nonpolar or semipolar).

Block 702 represents depositing the lower or first cladding layer 110 on the n-GaN layer 108. The first cladding layer 110, deposited on the n-GaN layer 108, may comprise a first material. A material composition and thickness of the bottom cladding layer may increase the modal confinement, resulting in lower threshold current density and improved lasing behavior, as compared to a symmetric LD structure.

Block 704 represents depositing a lower or first waveguiding layer 112 on the first cladding layer 110.

Block 706 represents depositing an active layer 114 on the lower or first waveguiding layer 112. For example, the active layer 114, deposited on the first waveguiding layer 112, may include an InGaN QW with an In composition sufficient to emit light having wavelengths corresponding to blue light (e.g., 440-460 nm), or wavelengths longer than blue light, or with an In composition of greater than 16%, or in the range 15-21%, for example. However, the In composition is not limited to a particular composition. The thickness of the QWs may be thicker than 4 nm, for example, however the present invention is not limited to a particular thickness. The QW may be an InGaN QW with InGaN or GaN barriers, for example.

Block 708 represents depositing an EBL 116 on the active layer 114.

Block 710 represents depositing an upper or second waveguiding layer 118 on the EBL layer 116. The first waveguiding layer 112 and the second waveguiding layer 118 may be comprised of different III-nitride material compositions. One or both of the first guiding layer 112 and the second guiding layer 118 may comprise InGaN with an In composition of greater than 5%.

Guiding layers 112, 118 are optically coupled to the active region 114, positioned (e.g., deposited on the first cladding layer 110 and EBL 116 respectively) to function as a waveguide for light emitted by the active layer 114 (e.g., reflecting the light so that it is confined between layers 112 and 118).

Block 712 represents depositing an upper or second cladding layer 124 on the second guiding layer 118. The second cladding layer 124, deposited on the guiding layer 118, may comprise a second material, for example, a material that has a higher refractive index than the refractive index of the first material (the cladding layer's 110 material). The first cladding layer 110 and the second cladding layer 124 may be comprised of different AlInGaN material compositions. The first cladding layer 110 and second cladding layer 124 may be comprised of material compositions other than AlGaN. The first cladding layer 110 and the second cladding layer 124 may be comprised of different AlGaN material compositions. For example, an aluminum (Al) composition of the first cladding layer 110 may be higher than an Al composition of the second cladding layer 124. Or, the first cladding layer 110 and the second cladding layer 124 may be comprised of different InGaN material compositions, for example.

Cladding layers 110, 124 are optically coupled to the waveguide layers 112, 118 and fabricated from materials that provide an index contrast to the waveguide layers 112, 118. The layers 110, 112 are positioned (e.g., deposited on layers 108 and 118) to function as, e.g., a mirror (for example), to help confine the optical mode generated by the active region 114 within or between the waveguide layers 112, 118, thereby preventing the mode's leakage into either the substrate 106 at the bottom or the metal at the top (e.g., the metal contact on layer 122).

Block 714 represents depositing at least one contact layer 122, e.g., on the upper or second cladding layer 124. Metal ohmic contacts may be deposited on layer 122.

Block 716 represents the end result of the method, a device such as the LD structure 104 illustrated in FIG. 1(c), comprising a light emitting active region 114 between a first cladding layer 110 and a second cladding layer 124, wherein (1) the first cladding layer 110 has a lower refractive index than a refractive index of the second cladding layer 124, thereby providing an asymmetric structure, and (2) the active region 114, the first cladding layer 110, and the second cladding layer 124 are comprised of III-nitride based material compositions. The active region 114 is typically between a first waveguiding layer 112 and a second waveguiding layer 118; the first waveguiding layer 112 is typically between the active region 114 and the first cladding layer 110, and the second waveguiding layer 118 is typically between the active region 114 and the second cladding layer 124.

In the example of FIG. 1(c), the first cladding layer 110 is AlGaN, the second cladding layer 124 is GaN, the first waveguiding layer 112 is InGaN, and the second waveguiding layer 118 is InGaN. For example, the first guiding layer 112 and the second guiding layer 118 may comprise InₓGa₁₋ₓN with x between 5 and 10%, the first cladding layer 110 may comprise n-Al_{0.05}Ga_{0.95}N, and the second cladding layer 124 may comprise p-GaN. This may create a balance between a high confinement factor Γ, greater than 2.5, and a low absorption coefficient α, smaller than 30 cm⁻¹, for example.

The layers 108-124 are typically epitaxially grown on top of one another, e.g., using (but not limited to) Metal Organic Vapor Phase Deposition (MOCVD), Molecular Beam Epitaxy (MBE), or Hydride Vapor Phase Epitaxy (HVPE) for example.)

Possible Modifications

1. This invention can be applied to polar, nonpolar and semipolar LDs.

2. This invention can be applied to any wavelength, ranging from UV to the green spectral range.

3. Any orientation of substrates could be used for this invention.

4. This invention can be applied to LD structures containing InGaN, GaN or AlInGaN waveguiding layers.

5. This invention can be applied to LD structures containing InGaN, AlGaN, GaN or AlInGaN barriers in the active region.

6. The lower cladding layer can be a quaternary alloy (AlInGaN) instead of ternary AlGaN based alloys.

7. The asymmetric design could also suggest a difference in AlGaN composition for the lower and upper cladding.

8. The asymmetric design could also include a structure with different InGaN composition for the lower and upper waveguide layers.

Advantages and Improvements

This invention has the following advantages compared to the symmetric cladded LD structures:

1. The use of an asymmetric clad in conjugation with a high Al containing AlGaN EBL helps to place the peak of the optical mode at the center of the active region (as shown in FIG. 2). In a symmetric cladded structure, the mode is pushed to the n-side by the AlGaN EBL, as also shown in FIG. 2.

2. The AlGaN bottom cladding also increases the modal confinement, resulting in lower threshold current density and improved lasing behavior. The confinement factor for asymmetric vs. symmetric (AlGaN clad-free) structures are Γ=2.53 and 2.37, respectively.

3. For example, the InGaN wave-guiding layers may mainly contribute to optical confinement, so that n-AlGaN layer can be used to control of peak position to achieve high optical confinement factor and low internal loss.

4. The present invention is a very easy way to tune the mode profile of a laser, and to control the far field pattern.

5. The AlGaN bottom cladding (e.g., on the n-side only) creates asymmetric in-plane strain, and this increases the ease of cleaving, as shown by the straighter edges and seamless cleaves in FIG. 6(a) as compared to 6(b). Otherwise, cleaving AlGaN clad-free LDs is not straightforward.

6. The use of AlGaN on the n-side only is novel because conventional commercial LDs use AlGaN on both the n- and p-sides, and the p-AlGaN hurts or is detrimental to electrical performance, carrier injection, and strain management, etc.

7. In a symmetric AlGaN cladded structure, p-AlGaN is used as the top clad. However, it is difficult to grow high quality p-AlGaN, and the hole concentration in p-AlGaN decreases with Al content due to increasing activation energy. Also, the conductivity of p-GaN is higher compared to p-AlGaN for the same growth temperature, resulting in higher hole injection efficiency for the former. Furthermore, GaN can be grown at a much faster rate than AlGaN, leading to lesser heat damage to the active region during the subsequent growth of the upper cladding layer.

The present invention enhances simplicity of the LD structure and epitaxy, and enables high power and high efficiency green InGaN injection lasers on nonpolar and semipolar substrates.

### REFERENCES

The following references are incorporated by reference herein.
[1] Kubota et al., Applied Physics Express 1 (2008), p. 011102.
[2] Tsuda et al., Applied Physics Express 1 (2008), p. 011104.
[3] Feezell et al., Japanese Journal of Applied Physics, Vol. 46, No. 13, 2007, pp. L284-L286.
[4] Farrell et al., Japanese Journal of Applied Physics, Vol. 46, No. 32, 2007, pp. L761-L763.
[5] Okamoto et. al., Appl. Phys. Express 1, p. 072201 (2008).
[6] Okamoto et. al., Jpn. J. Appl. Phys. 46, L820 (2007).\
[7] Lee et. al., J. Crystal Growth 310, p. 3881 (2008).
[8] Nagamatsu et. al., Phys. Status Solidi C, p. 1 (2009).
[9] You-Da Lin, Chia-Yen Huang, Matthew T. Hardy, Po Shan Hsu, Kenji Fujito, Arpan Chakraborty, Hiroaki Ohta, James S. Speck, Steven P. DenBaars, and Shuji Nakamura, entitled “m-plane Pure Blue Laser Diodes with p-GaN/n-AlGaN-based Asymmetric cladding and InGaN-based wave-guiding layers,” Applied Physics Letters Vol. 95, Issue 8, p. 081110 (2009).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A III-nitride based laser diode structure, comprising:
a light emitting active region between a first cladding layer and a second cladding layer, wherein:
(1) a refractive index of the first cladding layer is lower than a refractive index of the second cladding layer, thereby providing an asymmetric structure,
(2) the active region, the first cladding layer, and the second cladding layer are comprised of III-nitride based material compositions, and
(3) the active region is nonpolar or semipolar, and is on a nonpolar or semipolar substrate.

2. The laser diode structure of claim 1, wherein:
the active region is between a first waveguiding layer and a second waveguiding layer;
the first waveguiding layer is between the active region and the first cladding layer, and the second waveguiding layer is between the active region and the second cladding layer; and
the first waveguiding layer and the second waveguiding layer are comprised of different III-nitride material compositions.

3. The laser diode structure of claim 1, wherein
the active region is between a first waveguiding layer and a second waveguiding layer;
the first waveguiding layer is between the active region and the first cladding layer, and the second waveguiding layer is between the active region and the second cladding layer; and
the first cladding layer is AlGaN, the second cladding layer is GaN, the first waveguiding layer is InGaN, and the second waveguiding layer is InGaN.

4. The laser diode structure of claim 1, wherein the first cladding layer and the second cladding layer are comprised of material compositions other than AlGaN.

5. The laser diode structure of claim 1, wherein the first cladding layer and the second cladding layer are comprised of different AlGaN material compositions.

6. The laser diode structure of claim 5, wherein an aluminum (Al) composition of the first cladding layer is higher than an Al composition of the second cladding layer.

7. The laser diode structure of claim 1, wherein the first cladding layer and the second cladding layer are comprised of different InGaN material compositions.

8. The laser diode structure of claim 1, wherein the first cladding layer and the second cladding layer are comprised of different AlInGaN material compositions.

9. The laser diode structure of claim 1, further comprising an aluminum containing electron blocking layer between the active region and the second cladding layer, wherein the first cladding layer, the second cladding layer, and the aluminum containing electron blocking layer place a peak of an optical mode of the light closer to a center of the active region as compared to a position of a peak of an optical mode in a symmetric cladded structure.

10. The laser diode structure of claim 1, wherein the second cladding layer is an upper cladding layer, the first cladding layer is a bottom cladding layer, and a thickness and material composition of the bottom cladding layer creates asymmetric in-plane strain, thereby increasing an ease of cleaving of the laser diode structure as compared to cleaving an AlGaN clad free laser diode structure.

11. The laser diode structure of claim 10, wherein a material composition and thickness of the bottom cladding layer increases the modal confinement, resulting in lower threshold current density and improved lasing behavior, as compared to a symmetric laser diode structure.

12. The laser diode of claim 1, further comprising a first facet and a second facet defining an optical cavity of the laser diode structure, wherein the first facet and the second facet are seamlessly cleaved facets as compared to cleaved facets of an AlGaN clad free laser diode structure.

13. (canceled)

14. The laser diode of claim 1, further comprising:
the first cladding layer, comprising a first material, deposited on an n-GaN layer;
a first waveguiding layer deposited on the first cladding layer;
the active layer deposited on the first waveguiding layer;
an electron blocking layer (EBL) deposited on the active layer;
a second waveguiding layer deposited on the EBL layer;
the second cladding layer, comprising a second material, deposited on the second waveguiding layer, wherein the refractive index of the second material is higher than the refractive index of the first material; and
a contact layer deposited on the second cladding layer.

15. The laser diode structure of claim 14, wherein the active layer includes an InGaN quantum well with an In composition sufficient to emit light having wavelengths corresponding to blue light, wavelengths longer than blue light, or with an In composition greater than 16%.

16. The laser diode structure of claim 14, wherein the first waveguiding layer and the second guiding layer comprise InGaN with an In composition greater than 5%.

17. The laser diode structure of claim 16, wherein the first waveguiding layer and the second waveguiding layer comprise InₓGa₁₋ₓN with x between 5 and 10%, the first cladding layer comprises n-Al_{0.05}Ga_{0.95}N, and the second cladding layer comprises p-GaN.

18. A method of fabricating a III-nitride laser diode structure, comprising:
depositing a light emitting active region on a non-polar or semi-polar substrate, so that the active layer is nonpolar or semipolar; and
providing an asymmetric structure by positioning the light emitting active region between a first cladding layer and a second cladding layer, wherein:
(1) a refractive index of the first cladding layer is lower than a refractive index of the second cladding layer, thereby providing an asymmetric structure, and
(2) the active region, the first cladding layer and the second cladding layer are comprised of III-nitride based material compositions.

19. The method of claim 18, wherein the positioning further comprises:
depositing the first cladding layer on an n-GaN layer;
depositing a first waveguiding layer on the first cladding layer;
depositing the active layer on the first waveguiding layer;
depositing electron blocking layer (EBL) on the active layer;
depositing a second waveguiding layer on the EBL layer;
depositing the second cladding layer on the second guiding layer, wherein the refractive index of the second cladding layer is higher than the refractive index of the second cladding layer material; and
depositing a contact layer on the second cladding layer.

20. The method of claim 16, further comprising depositing the n-GaN layer on the non-polar or semi-polar substrate.
